(19) United States
(12) Patent Application Publication
(10) Pub. No.: US 2023/0387093 A1
(43) Pub. Date: Nov. 30, 2023

(54) DISPLAY DEVICE

(71) Applicant: Hubei Yangtze Industrial Innovation Center of Advanced Display Co., LTD., Wuhan (CN)

(72) Inventor: Sitao HUO, Shanghai (CN)

(21) Appl. No.: 17/942,518

(22) Filed: Sep. 12, 2022

(30) Foreign Application Priority Data
May 26, 2022 (CN) 202210585965.6

(51) Int. Cl. H01L 25/16; H01L 31/0232; H01L 27/15

(52) U.S. Cl. CPC H01L 25/167; H01L 25/162; H01L 31/02327; H01L 27/156; G06V 40/1318

(57) ABSTRACT

A display device is provided. The display device includes a substrate; light-emitting devices on a side of the substrate; light transmission structures on a side of the light-emitting devices away from the substrate; and a plurality of photosensitive units on a side of the substrate away from the light-emitting device. Each of the light transmission structures includes a first light guide element and reflectors arranged along a direction parallel to a plane of the substrate. The reflectors are located at two sides of the first light guide element. An orthographical projection of the first light guide element to the substrate is located between two corresponding adjacent light-emitting devices. The first light guide element has a refractive index n₁ and the reflectors have a refractive index n₀, wherein n₁≠n₀.

### CROSS-REFERENCE TO RELATED APPLICATION

This application claims the priority of Chinese Patent Application No. 202210585965.6, filed on May 26, 2022, the content of which is incorporated herein by reference in its entirety.

### TECHNICAL FIELD

The present disclosure generally relates to the field of display technologies and, more particularly, relates to a display device.

### BACKGROUND

With popularity of mobile display products, information security has attracted much attention. Fingerprints are invariable features of human elements that are inherently unique and distinguishable from others. A fingerprint consists of a series of ridges and valleys on a skin surface of a fingertip. Details of these ridges and valleys usually include ridge bifurcation, ridge ends, arches, tent arches, left-handed, right-handed, helical or double-handed. These details determine the uniqueness of the fingerprint pattern. Because fingerprints have advantages of uniqueness, difficulty to copy, security, etc., fingerprint recognition technology has been widely used in mobile display products as a way of identity authentication and access control in recent years, such that the security and ease of operation of the mobile display products are improved.

Light fingerprint recognition uses the principle of refraction and reflection of light. When a finger is placed on a light lens, and difference between the sensor device receiving different fingerprint information is achieved and a fingerprint image is formed through the difference in the reflection of light on the ridges and valleys on the surface of the finger. The working principle is relatively simple, but it is difficult to improve the accuracy of fingerprint identification because the sensing device used in the fingerprint identification process is easily affected by light noise.

Therefore, how to improve the accuracy of light fingerprint recognition is one of the technical problems to be solved.

### SUMMARY

One aspect of the present disclosure provides a display device. The display device includes a substrate; light-emitting devices on a side of the substrate; light transmission structures on a side of the light-emitting devices away from the substrate; and a plurality of photosensitive units on a side of the substrate away from the light-emitting device. Each of the light transmission structures includes a first light guide element and reflectors arranged along a direction parallel to a plane of the substrate. The reflectors are located at two sides of the first light guide element. An orthographical projection of the first light guide element to the substrate is located between two corresponding adjacent light-emitting devices. The first light guide element has a refractive index n₁ and the reflectors have a refractive index no, wherein n₁≠n₀.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a top view of an exemplary display device consistent with various disclosed embodiments in the present disclosure;

FIG. 2 illustrates a locally magnified view of a display region in the display device in FIG. 1 consistent with various disclosed embodiments in the present disclosure;

FIG. 3 illustrates a cross-sectional view of the display device in FIG. 2 along an AA direction, consistent with various disclosed embodiments in the present disclosure;

FIG. 4 illustrates another locally magnified view of a display region in the display device in FIG. 1 consistent with various disclosed embodiments in the present disclosure;

FIG. 5 illustrates a cross-sectional view of the display device in FIG. 4 along a BB direction, consistent with various disclosed embodiments in the present disclosure;

FIG. 6 illustrates another locally magnified view of a display region in the display device in FIG. 1 consistent with various disclosed embodiments in the present disclosure;

FIG. 7 illustrates a cross-sectional view of the display device in FIG. 6 along a CC direction, consistent with various disclosed embodiments in the present disclosure;

FIG. 8 illustrates another locally magnified view of a display region in the display device in FIG. 1 consistent with various disclosed embodiments in the present disclosure;

FIG. 9 illustrates another locally magnified view of a display region in the display device in FIG. 1 consistent with various disclosed embodiments in the present disclosure;

FIG. 10 illustrates another locally magnified view of a display region in the display device in FIG. 1 consistent with various disclosed embodiments in the present disclosure;

FIG. 11 illustrates another locally magnified view of a display region in the display device in FIG. 1 consistent with various disclosed embodiments in the present disclosure;

FIG. 12 illustrates another locally magnified view of a display region in the display device in FIG. 1 consistent with various disclosed embodiments in the present disclosure;

FIG. 13 illustrates a relative positional relationship between second light guide elements and pixel units in a display device consistent with various disclosed embodiments in the present disclosure;

FIG. 14 illustrates a top view relationship between first light guide elements and photosensitive units in a display device consistent with various disclosed embodiments in the present disclosure;

FIG. 15 illustrates a cross-sectional view of the display device in FIG. 14 along a DD direction, consistent with various disclosed embodiments in the present disclosure; and

FIG. 16 illustrates a schematic of film layers of a display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

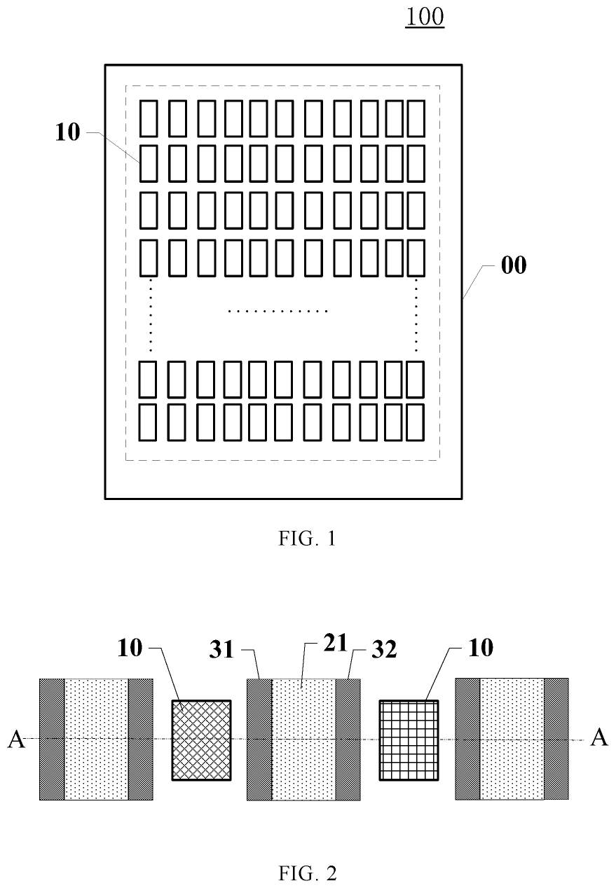

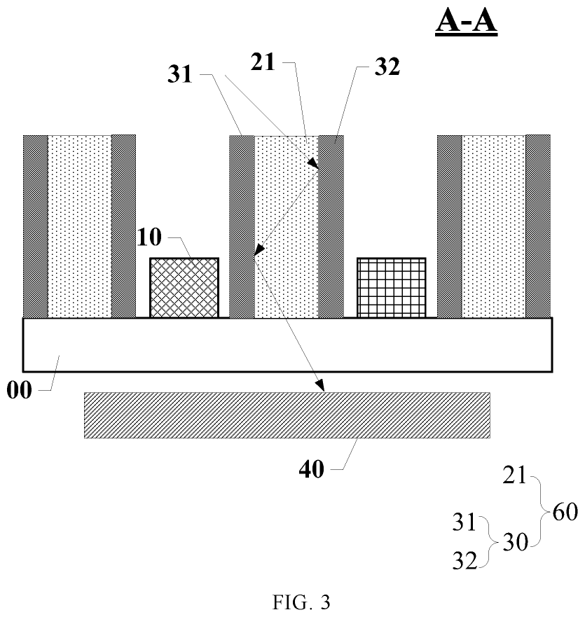

The present disclosure provides a display device. FIG. 1 illustrates a top view of an exemplary display device according to one embodiment of the present disclosure, FIG. 2 illustrates a locally magnified view of a display region in the display device shown in FIG. 1, and FIG. 3 illustrates a cross-sectional view of the display device in FIG. 2 along an AA direction. As shown in FIG. 1 to FIG. 3, in one embodiment, the display device 100 may include a substrate 00, light-emitting devices 10 disposed at a side of the substrate 00, light transmission structures 60 disposed at a side of the light-emitting devices 10 away from the substrate 00, and a plurality of photosensitive units 40 disposed at a side of the substrate 00 away from the light-emitting devices 10.

Each of the light transmission structures 60 may include a first light guide element 21 and a reflector 30 arranged along a direction parallel to a plane of the substrate 00. The reflector 30 may be disposed at two sides of the first light guide element 21. An orthographical projection of a first light guide element 21 to the substrate 00 may be located between two corresponding adjacent light-emitting devices 10. The first light guide element 21 may have a refractive index n₁, and the reflector 30 may have a refractive index n₀, where n₁≠n₀.

For description purposes only, the embodiment in FIG. 1 where the display device has a rectangular structure is used as an example to illustrate the present disclosure, and does not limit the actual shape of the display device. In some other embodiments of the present disclosure, the display device may also be embodied in a shape other than a rectangle, such as circular, oval or non-rectangular shaped structures. Also, the embodiment in FIG. 1 and FIG. 2 where the light-emitting devices 10 have rectangular structures is used as an example to illustrate the present disclosure, and does not limit the actual shapes of the light-emitting devices 10. In some other embodiments of the present disclosure, light-emitting devices 10 may also be embodied in other structures such as circles or diamonds. Also, in FIG. 1, the arrangement of the light-emitting devices 10 arranged in an array is only a schematic and an example to illustrate the present disclosure, and the actual arrangement of the light-emitting devices 10 is not limited. In other embodiments of the present disclosure, the light-emitting devices 10 may also be arranged in some other suitable ways.

To clearly illustrate the content of the present disclosure, only the structures related to the present disclosure are shown in the drawings of the present disclosure. Although not shown in the drawings, it should be understood that, to drive the light-emitting devices 10 to emit light, the display device may further include a plurality of signal lines, such as gate lines, data lines, clock signal lines, etc., and may also include a plurality of driving circuits, such as a pixel driving circuit located in the display area, a gate driving circuit located in a non-display area, and so on.

As shown in FIG. 1 to FIG. 3, in the display device, the light transmission structures 60 may be provided on the side of the light-emitting devices 10 away from the substrate 00, and a plurality of photosensitive units 40 may be provided on the side of the substrate 00 away from the light-emitting devices10. Optionally, in some embodiments, the plurality of photosensitive units 40 may be units with photosensitive function such as fingerprint recognition units or infrared sensing units. For example, the plurality of photosensitive unit 40 may be the fingerprint recognition units, and a touch body may be pressed on the screen of the display device. The finger may have ridges and valleys. The ridges may be in contact with the surface of the display screen, and the valleys may be not in contact with the surface of the display screen. Correspondingly, the light may have different reflectivity when shinning on the valleys and ridges of the fingerprint, such that the reflected light formed at the positions of the ridges and the reflected light formed at the positions of the valleys received by the plurality of photosensitive units 40 have different intensities. Correspondingly, photocurrents converted from the reflected light formed at the positions of the ridges and the reflected light formed at the positions of the valleys may have different magnitudes in the plurality of photosensitive units 40. The ridges and valleys of the fingerprint may be identified according to the magnitude of the photocurrents. The magnitude of the currents of the plurality of photosensitive units 40 may be integrated to identify the fingerprint information. In the existing technologies, since the sensing device used in the fingerprint identification process is easily affected by light noise, it is difficult to improve the accuracy of the fingerprint identification.

In the present disclosure, the light transmission structures 60 may be disposed in the display device. Each light transmission structure 60 may include the first light guide element 21 and the reflectors 30 disposed at two sides of the first light guide element 21. Along a direction perpendicular to the substrate 00, a first light guide element 21 may be located between two adjacent light-emitting devices 10. In one embodiment, an area where the light-emitting devices 10 are provided in the display device is an open area, and an area where the light-emitting devices 10 are not provided (for example, an area between two adjacent light-emitting devices 10) may be a non-open area. Optionally, in one embodiment, the first light guide element 21 and the reflectors 30 in the light transmission structure 60 may be both located in a non-open area, to avoid blocking the light emitted by the light-emitting devices 10 and affecting the aperture ratio of the display device. Further, in one embodiment, the refractive index of the first light guide element 21 in the light transmission structure 60 may be different from the refractive index of the reflectors 30. Correspondingly, when the light is transmitted to an interface between the first light guide element 21 and the reflector 30, reflection may occur and the first light guide element 21 may form a light guide channel. The light may be transmitted through the first light guide element 21 to the area between the two adjacent light-emitting devices 10, and then may be conducted to the plurality of photosensitive units 40 at the side of the substrate 00 away from the light-emitting devices 10 from this area. The above arrangement of the light guide channel may be beneficial to increase the amount of light transmitted to the plurality of photosensitive units 40. When the amount of light received by the plurality of photosensitive units 40 is increased, it may be beneficial to improve the photosensitive performance of the product. When the plurality of photosensitive units 40 disposed on the side of the substrate 00 away from the light-emitting devices 10 are fingerprint identification units, the above-mentioned light guide channels may transmit more light to the fingerprint identification units, thereby helping to improve the fingerprint identification accuracy of the product.

In one embodiment, the refractive index n₁ of the first light guide element 21 and the refractive index no of the reflectors 30 may have a relationship of n₁>n₀.

In the present embodiment, the refractive index n₁ of the first light guide element 21 may be larger than the refractive index no of the reflectors 30 at two sides of the first light guide element 21. Correspondingly, when the light transmits from the first light guide element 21 to the reflectors 30, it may be equivalent to transmitting from a medium with a large refractive index to a medium with a small refractive index. In this way, at least a part of the light may be reflected back to the first light guide element 21 at the interface. The light may be continuously reflected by the reflectors 30 in the first light guide element 21, and may be further directed to the plurality of photosensitive units 40. Therefore, the effective utilization rate of the light transmitted in the first light guide element 21 may be effectively improved, and the amount of light transmitted to the plurality of photosensitive units 40 via the first light guide element 21 may be effectively increased, which is beneficial to improve the light sensitivity of the plurality of photosensitive units 40.

In one embodiment shown in FIG. 2 and FIG. 3, the reflectors 30 corresponding to one first light guide element 21 may include a first reflector 31 and a second reflector 32 respectively disposed at two sides of the first light guide element 21. The refractive index of the first reflector 31 is n₀₁, and the refractive index of the second reflector 32 is n₀₂, where n₀₁=n₀₂.

Specifically, in one embodiment, the refractive indices of the first reflector 31 and the second reflector 32 disposed respectively at two sides of the first light guide element 21 are set to be the same. When the incident angles of the light transmitted from the first light guide element 21 to the first reflector 31 and the light transmitted from the first light guide element 21 to the second reflector 32 are same, the reflection angles may also be the same, that is, the first reflector 31 and the second reflector 32 may have the same ability to reflect light, which may be beneficial to improve the uniformity of the overall light guide of the light transmission structures.

Of course, in some other embodiments of the present disclosure, the refractive indices of the first reflector 31 and the second reflector 32 located respectively at two sides of the same first light guide element 21 may also be set to be different. Since the refractive index of the first reflector 31 and the refractive index of the second reflector 32 may be both smaller than the refractive index of the first light guide element 21, the light emitted to the first reflector 31 and the second reflector 32 through the first light guide element 21 may be further reflected to the first light guide element 21 and then may be further directed to the area between the light-emitting devices 10 to be conducted to the plurality of photosensitive units 40, which may be also beneficial to improve the photosensitive performance of the plurality of photosensitive units 40.

In an optional embodiment of the present disclosure, the first reflector 31 and the second reflector 32 may be made of a same material.

Specifically, when the first reflector 31 and the second reflector 32 located respectively at two sides of the first light guide element 21 are made of the same material, the first reflector 31 and the second reflector 32 may be formed in a same manufacturing process, which may be beneficial to simplify the overall manufacturing process of the display device and improve the production efficiency.

In one embodiment, along a direction from the first reflector 31 to the second reflector 32, a thickness of the first reflector 31 may be same as a thickness of the second reflector 32.

When the thickness of the first reflector 31 and the second reflector 32 located respectively at two sides of the first light guide element 21 is smaller, the area occupied by the first reflector 31 and the second reflector 32 in the display area of the display device may be smaller, which is more beneficial to improve the pixel density of the display device. In the present disclosure, the thicknesses of the first reflector 31 and the second reflector 32 may be set to be the same, and there may be no need to manufacture the first reflector 31 and the second reflector 32 respectively according to different thickness specifications, which may be beneficial to simplify the manufacturing process of the first reflector 31 and the second reflector 32 and improve the production efficiency of the display device.

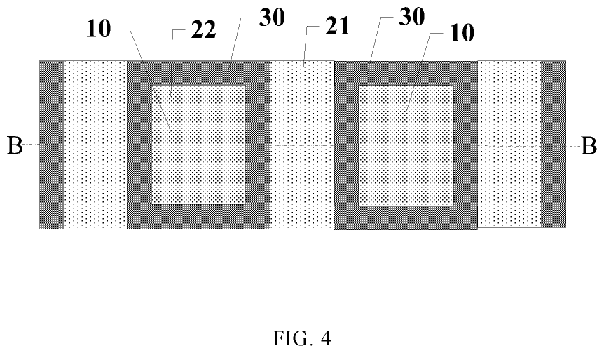

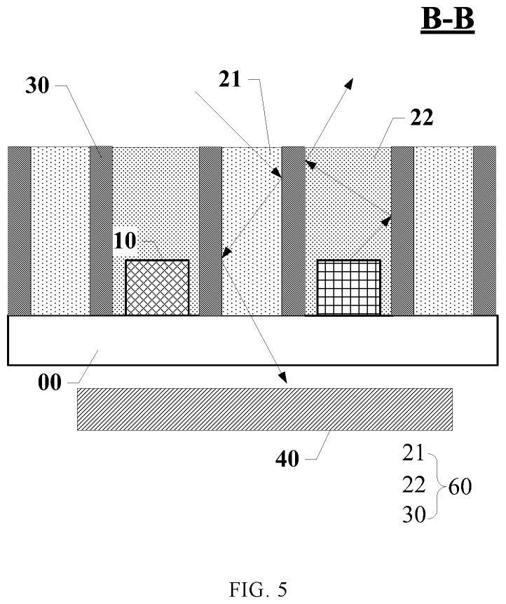

FIG. 4 illustrate another locally magnified view of the display region of the display device in FIG. 1, and FIG. 5 is a cross-sectional view of the display device in FIG. 4 along a BB direction. As shown in FIG. 4 and FIG. 5, in another embodiment of the present disclosure, the light transmission structures 60 may further include a plurality of second light guide elements 22. Along a first direction, the plurality of second light guide elements 22 may cover the light-emitting devices 10. The plurality of second light guide elements 22 may have a refractive index n₂, and n₂>n₀. The first direction may be perpendicular to the substrate 00.

In the display device provided by the present embodiment of the present disclosure, the light transmission structures 60 may further include the plurality of second light guide elements 22, besides the first light guide elements 21 and the reflectors 30. The plurality of second light guide elements 22 may cover the light-emitting devices 10, that is, the plurality of second light guide elements 22 may cover upper surfaces and side surfaces of the light-emitting devices 10. Optionally, in one embodiment, one reflector 30 may be located on an outer side surface of a corresponding one of the plurality of second light guide elements 22. In the present embodiment of the present disclosure, the refractive index of the second light guide element 22 may be configured to be larger than the refractive index of the reflectors 30. When the light emitted by the light-emitting devices 10 is emitted from the plurality of second light guide elements 22 to the interfaces between the reflectors 30 and the plurality of second light guide elements 22, it may be equivalent to transmitting from a medium with a large refractive index to a medium with a small refractive index. In this way, at least a part of the light may be reflected back to the plurality second light guide elements 22 at the interfaces between the reflectors 30 and the plurality of second light guide elements 22. The light may be continuously reflected by the reflectors 30 in the plurality of second light guide elements, and may be eventually be emitted to a light-emitting surface of the display device. By providing the plurality of second light guide elements 22 in the display device, a light guide channel may be provided for the light-emitting devices 10, such that most of the light emitted by the light-emitting devices 10 may be directed to the light-emitting surface of the display device, which may be beneficial to improve the effective utilization of the light emitted by the light-emitting devices 10 and improve the overall brightness of the display device.

As shown in FIG. 4 and FIG. 5, in one embodiment, the refractive index of the first light guide element 21 and the refractive index of the plurality of second light guide elements 22 may satisfy: n₁=n₂.

Specifically, in the present embodiment, the refractive index of the first light guide element 21 and the refractive index of the plurality of second light guide elements 22 may be configured to be same, and the first light guide element 21 and the plurality of second light guide elements 22 may be made of a same material. Further, the first light guide element 21 and the plurality of second light guide elements 22 may be formed in a same process. The types of constituent materials of the film layers included in the display device may be simplified. Also, the production efficiency of the display device may be improved and the production cost may be reduced.

As shown in FIG. 4 and FIG. 5, in one embodiment, along the first direction, each of the plurality of second light guide elements 22 may cover one light-emitting device 10.

Specifically, in the display device provided in this embodiment, when the plurality of second light guide elements 22 is introduced, optionally, the plurality of second light guide elements 22 and the light-emitting devices 10 may be arranged in a one-to-one correspondence, that is, one of the plurality of second light guide elements 22 may only cover one light-emitting device 10. That may be equivalent to introducing a separate light guide channel for each light-emitting device 10, and the light emitted by each light-emitting device 10 may be directed to the light-emitting surface of the display device through the light guiding effect of the plurality of second light guide elements 22. The effective utilization rate of the light emitted by each light-emitting device 10 may be improved, which may be more beneficial to improve the overall display brightness of the display device and improve the display effect.

As shown in FIG. 4 and FIG. 5, in one embodiment, each reflector 30 may disposed around a corresponding one of the plurality of second light guide elements 22.

Specifically, when the plurality of second light guide elements 22 are introduced on the light-emitting side of the light-emitting devices 10, in the present embodiment, one reflector 30 may be introduced for each of the plurality of second light guide elements 22, and each reflector 30 may surround the corresponding one of the plurality of second light guide elements 22. Optionally, the side surfaces of each of the plurality of second light guide elements 22 may be all covered by one corresponding reflector 30. When a portion of the light emitted by the light-emitting devices 10 is directed to the sides of the plurality of second light guide elements 22 in any direction, since the sides of the plurality of second light guide elements 22 are surrounded by the reflectors 30, this portion of the light may be reflected by the reflectors 30 and may enter the plurality of second light guide elements 22 again. And after multiple reflections, it may be directed to the light-emitting surface of the display device. By disposing each reflector 30 around a corresponding one of the plurality of second light guide elements 22, the light emitted by the light-emitting devices10 that originally may not be directed to the light-emitting surface is able to be effectively utilized, and this portion of the light may finally be directed to the light-emitting surface of the display device after the reflection of the plurality of second light guide elements 22 and the reflectors 30. The effective utilization of the light of the light-emitting devices 10 may be further improved by the plurality of second light guide elements 22, which may be further beneficial to improving the overall brightness of the display device.

Optionally, the reflectors around the first light guide elements 21 and the reflectors around the plurality of second light guide elements 22 may be made of the same material and multiplexed with each other. For example, the reflectors located between the first light guide elements 21 and the plurality of second light guide elements 22 may reflect both the light in the first light guide elements 21 and the light in the plurality of second light guide elements 22.

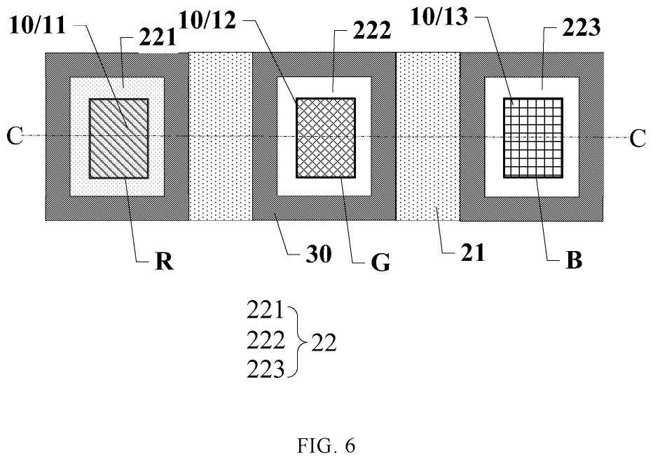

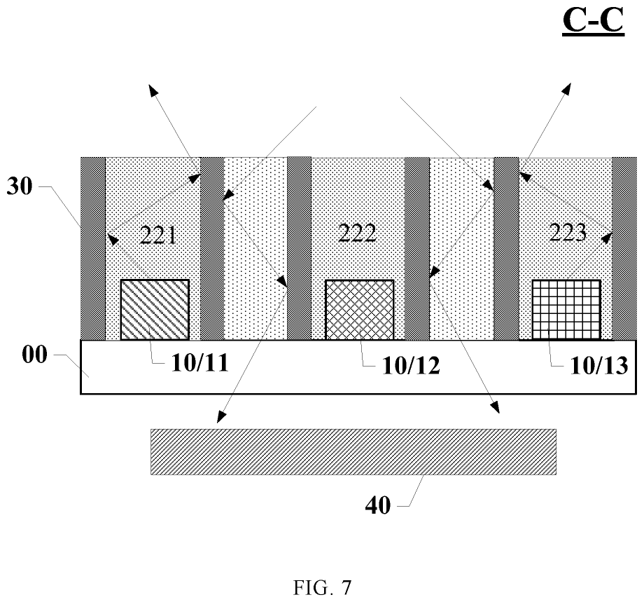

FIG. 6 illustrate another locally magnified view of the display region of the display device in FIG. 1, and FIG. 7 is a cross-sectional view of the display device in FIG. 6 along a CC direction. As shown in FIG. 6 and FIG. 7, in another embodiment of the present disclosure, the light-emitting devices 10 may include first-color light-emitting devices 11, second-color light-emitting devices 12, and third-color light-emitting devices 13. Second light guide elements 22 of the plurality of second light guide elements 22 corresponding to the first-color light-emitting devices 11, the second-color light-emitting devices 12, and the third-color light-emitting devices 13 may have same refractive indices.

Specifically, the present embodiment illustrates an exemplary relative positional relationship between each light-emitting device 10, a corresponding one of the plurality of second light guide elements 22, and corresponding reflectors 30, when the light-emitting devices 10 in the display device include light-emitting devices with three different colors. When the light-emitting devices 10 in the display device include light-emitting devices with three different colors, in the present disclosure, a corresponding second light guide element 22 and corresponding reflectors 30 surrounding the second light guide element 22 may be disposed for each light-emitting device 10. The light emitted by the light-emitting devices 10 with different light-emitting colors may be emitted to the light-emitting surface of the display device through the corresponding second light guide elements 22 of the plurality of second light guide elements 22. The reflectors 30 may also play the role of blocking walls to avoid mixing of the light emitted by the light-emitting devices 10 with different light-emitting colors. In this embodiment, the refractive indices of the plurality of second light guide elements 22 corresponding to the light-emitting devices 10 with different luminous colors may be configured to be the same. Therefore, each of the plurality of second light guide elements 22 may be made of the same material, and there may be no need to perform differential design for the second light guide elements 22 for the light-emitting devices 10 with different luminescence colors. The manufacture of each second light guide element 22 may be completed in the same manufacturing process, which may be beneficial to simplify the manufacturing process of the display device and improve the production efficiency of the display panel.

As shown in FIG. 6 and FIG. 7, in one embodiment, the light-emitting devices 10 may include the first-color light-emitting devices 11, the second-color light-emitting devices 12, and the third-color light-emitting devices 13. The refractive index of the second light guide elements 221 corresponding to the light-emitting devices 11 of the first color is n₂₁, the refractive index of the second light guide elements 222 corresponding to the light-emitting devices 12 of the second color is n₂₂, and the refractive index of the second light guide elements 223 corresponding to the light-emitting devices 13 of the third color is n₂₃. The refractive index of the reflectors 30 corresponding to the light-emitting devices 11 of the first color is n₀₁, the refractive index of the reflectors 30 corresponding to the light-emitting devices 12 of the second color is n₀₂, and the refractive index of the reflectors 30 corresponding to the light-emitting devices 13 of the third color is n₀₃. n₂₁-n₀₁−n₂₂-n₂=n₂₃−n₀₃.

As shown in FIG. 6 and FIG. 7, in one embodiment, the light-emitting devices 10 with different luminescent colors may be provided with different second light guide elements 22, and each second light guide elements 22 may be surrounded by different reflectors 30. In the present embodiment, for each light-emitting device 10, the difference between the refractive index of the corresponding second light guide element 22 and the refractive index of the corresponding reflector 30 may be configured, such that the difference between the refractive index of the second light guide element 22 and the refractive index of the reflector 30 corresponding to one of the first-color light-emitting devices 10, n₂₁i-n₀₁, the difference between the refractive index of the second light guide element 22 and the refractive index of the reflector 30 corresponding to one of the second-color light-emitting devices 10, n₂₂-n₀₂, and the difference between the refractive index of the second light guide element 22 and the refractive index of the reflector 30 corresponding to one of the third-color light-emitting devices 10, n₂₃-n₀₃, are same. Correspondingly, the second light guide elements 22 and the reflectors 30 corresponding to the light-emitting devices 10 of different luminous colors may have the same reflective ability to light of different colors, which may be beneficial to improve the overall brightness uniformity of the display device. Further, when the refractive indices of the second light guide elements 22 corresponding to the light-emitting devices 10 of different luminous colors are the same, the refractive indices of the reflectors 30 corresponding to the light-emitting devices 10 of different luminous colors may also be the same. Correspondingly, when each second light guide element 22 is made of the same material in the same process, each reflector 30 may also be made of the same material in another process, which may be beneficial to simplify the manufacturing process of the display device and improve the production efficiency of the display device.

As shown in FIG. 6 and FIG. 7, in another embodiment, the light-emitting devices 10 may include red light-emitting devices R, green light-emitting devices G, and blue light-emitting devices B. The refractive index of the second light guide elements corresponding to the red light-emitting devices R is n₂₁, the refractive index of the second light guide elements 222 corresponding to the green light-emitting devices G is n₂₂, and the refractive index of the second light guide elements 223 corresponding to the blue light-emitting devices B is n₂₃. The refractive index of the reflectors 30 corresponding to the red light-emitting devices R is n₀₁, the refractive index of the reflectors 30 corresponding to the green light-emitting devices G is n₀₂, and the refractive index of the reflectors 30 corresponding to the blue light-emitting devices B is n₀₃. n₂₃−n₀₃>n₂₂-n₀₂>n₂₁−n₀₁.

In the present embodiment, the light-emitting devices 10 may be Micro LEDs or Mini LEDs. Generally, the red light-emitting devices R may have the highest light-emitting efficiency, the blue light-emitting devices B may have the lowest light-emitting efficiency, and the green light-emitting devices may have the intermediate light-emitting efficiency. To balance the difference in the light-emitting efficiency of the light-emitting devices 10 of different colors, in this embodiment, the difference in refractive index between the second light guide element 22 and the reflector 30 corresponding to the blue light-emitting device B may be set to the maximum value. Correspondingly, more light emitted by the blue light-emitting devices B may be directed to the light-emitting surface of the display device under the action of the second light guide elements 22 and the reflectors 30, to improve the luminous brightness of the blue light-emitting devices B with low luminous efficiency. The difference in refractive index between the second light guide elements 22 and the reflectors 30 corresponding to the green light-emitting device G may be set to the intermediate value, and the difference in refractive index between the second light guide elements 22 and the reflectors 30 corresponding to the red light-emitting device R may be set to the smallest value, to reduce the difference in the light emitted from the light-emitting devices 10 of different light-emitting efficiency to the light-emitting surface of the display device. The real light-emitting efficiency of the light-emitting devices 10 of different light-emitting colors may be balanced, to further improve the display effect of the display device.

As shown in FIG. 6 and FIG. 7, in one embodiment, along an arrangement direction of the light-emitting devices 10, a width of an interval between any two adjacent reflectors 30 may be same.

In the present embodiment, the width of the interval between any two adjacent reflectors 30 may be same, and different reflectors 30 may be formed according to the same interval specifications. It is unnecessary to perform differential design on the intervals of different reflectors 30. Therefore, the manufacturing process of the display device may be simplified and the production efficiency of the display device may be improved, while improving the light-emitting efficiency of the display device through the reflectors 30 and the light guide elements.

As shown in FIG. 6 and FIG. 7, a contour shape of an orthographic projection of one light-emitting device 10 on the substrate 00 may be same as a contour shape of an orthographic projection of one reflector 30 corresponding to the light-emitting device 10 on the substrate 00.

Specifically, when the second light guide elements 22 are introduced for the light-emitting devices 10, the reflectors 30 may be arranged around the second light guide elements 22. When the contour shape of the orthographic projection of one light-emitting device 10 and the contour shape of the orthographic projection of the reflector 30 corresponding to the light-emitting device 10 are configured to be same, the connection between the interface between the reflector 30 and one corresponding second light guide element 22 may be more reliable, and the coating of the reflector 30 to the corresponding second light guide element 22 may be better, which may be beneficial to realize the light reflection.

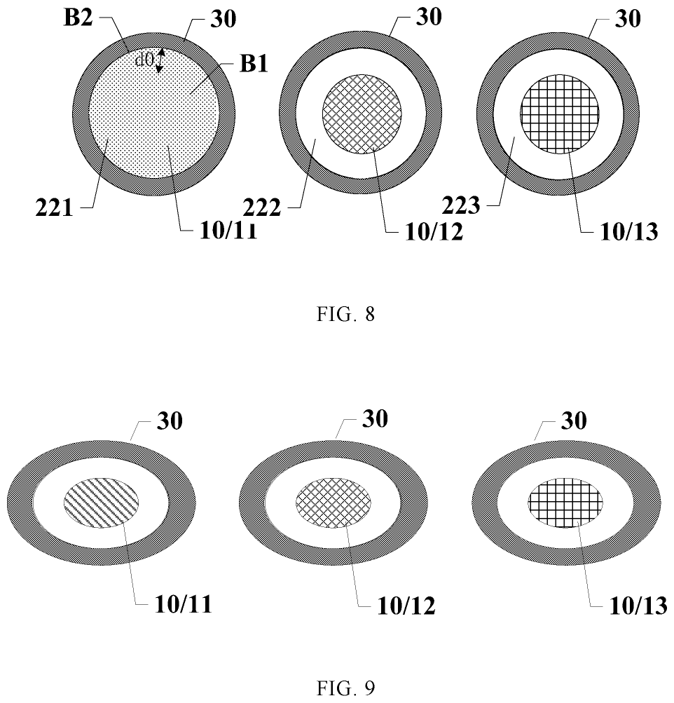

For description purposes only, the above embodiment where the contour shape of the orthographic projection of one light-emitting device 10 and the contour shape of the orthographic projection of the reflector 30 corresponding to the light-emitting device 10 on the substrate 00 are rectangles is used as an example to illustrate the present disclosure, and does not limit the scope of the present disclosure. In some other embodiments, the contour shape of the orthographic projection of one light-emitting device 10 and the contour shape of the orthographic projection of the reflector 30 corresponding to the light-emitting device 10 on the substrate 00 may adopt other suitable shapes. For example, the contour shape of the orthographic projection of one light-emitting device 10 and the contour shape of the orthographic projection of the reflector 30 corresponding to the light-emitting device 10 on the substrate 00 may be configured to circles in one embodiment in FIG. 8, or ovals in another embodiment in FIG. 9, where FIG. 8 and FIG. 9 are other locally magnified view of the display region of the display device in FIG. 1. The present disclosure has no limit on this.

As shown in FIG. 6 and FIG. 8, in one embodiment, an outer edge of the contour shape of the orthographic projection of one light-emitting device 10 on the substrate 00 may be a first edge B1, and an inner edge of the contour shape of the orthographic projection of the reflector 30 corresponding to the light-emitting device 10 on the substrate 00 may be a second edge B2. A distance d0 between the first edge B1 and the second edge B2 may be same.

When the distance d0 between the outer edge of the contour of the orthographic projection of the light-emitting device 10 on the substrate 00 and the inner edge of the corresponding reflector 30 of the orthographic projection on the substrate 00 is set equal, the interval between one light-emitting device 10 and its corresponding reflector 30 may be relatively uniform, and the distance of the light of the same angle emitted by the light-emitting device 10 to the reflector 30 may be also more uniform, which is beneficial to improve the uniformity of the reflection efficiency of the reflectors 30 to the light emitted by the light-emitting devices 10 from different directions. Therefore, the overall light-emitting efficiency of the light-emitting devices 10 may be improved.

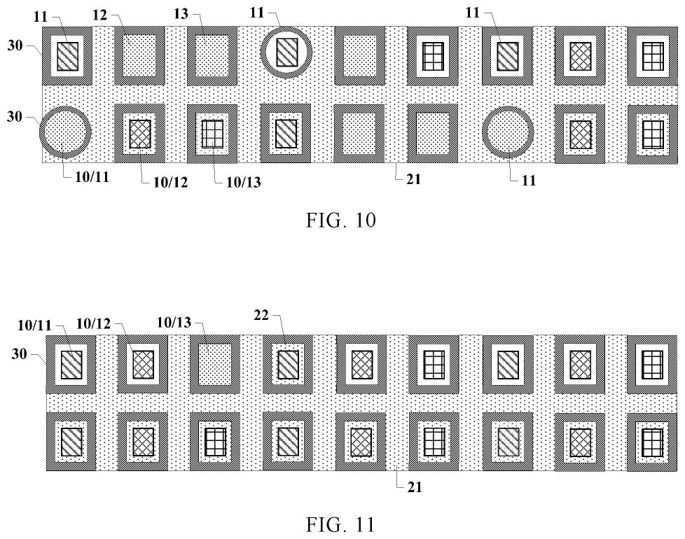

In the above embodiment, the contour shape of the orthographic projection of each light-emitting device 10 and the shape of the orthographic projection of the corresponding reflector 30 on the substrate 00 may be set to same. In some other embodiments, the contour shapes of the orthographic projection of the light-emitting devices 10 and the shapes of the orthographic projection of the corresponding reflectors 30 on the substrate 00 may be set to different. For example, in one embodiment shown in FIG. 10 which illustrates another locally magnified view of the display region of the display device in FIG. 1, the orthographic projection of the reflectors 30 corresponding to the light-emitting devices 10 of same light-emitting color on the substrate 00 may have different shapes. The reflectors 30 corresponding to the light-emitting devices 10 with one same light-emitting color may have a first shape and a second shape. The reflectors 30 with the first shape and with the second shape may be arranged alternately.

In FIG. 10, the light-emitting devices 10 with the same light-emitting color are denoted by same filling patterns, and different filling patterns are used to distinguish the light-emitting devices 10 with different light-emitting colors. For example, for the first-color light-emitting devices 11, the contour shape of the orthographic projection of each first color light-emitting device 10 may be same (in the present embodiment, a rectangle is used as an example). Therefore, the manufacturing process of the light-emitting devices 10 with the same light-emitting color may be simplified and the production efficiency may be improved. The shapes of the orthographic projection of the reflectors 30 corresponding to the first-color light-emitting devices 10 on the substrate 00 may include a first shape (a circle is used as an example) and a second shape (a rectangle is used as an example), and one of the first shape and the second shape may be same as the contour shape of the orthographic projection of the corresponding first color light-emitting devices 10, or both the first shape and the second shape may be different from the contour shape of the orthographic projection of the corresponding first color light-emitting devices 10. The present disclosure has no limit on this. When the first color light-emitting devices 10 have the highest light-emitting efficiency in comparison to the second-color light-emitting devices 12 and the third-color light-emitting devices 13, by setting at least a portion of the reflectors corresponding to the first-color light-emitting devices 10 to have the orthographical projection contours different from the contour shape of the orthographic projection of the first color light-emitting devices 11, the light-emitting amount of the first-color light-emitting devices 11 may be relatively reduced. Therefore, the difference of the light-emitting efficiency of the light-emitting devices 10 of different light-emitting colors may be balanced, to further improve the display effect of the display device.

Further, in the present embodiment, the first shape and the second shape may be arranged alternately along the arrangement direction of the light-emitting devices 10. Therefore, the uniformity of the overall light-emitting brightness of the light-emitting devices 10 with the same light-emitting color in the display device may be improved, to avoid local over-brightness or local over-darkness, and the display effect may be improved.

In one embodiment, for one light-emitting device 10 with low light-emitting efficiency, the contour shape of the orthographical projector of the corresponding reflectors 30 may be configured to be same, to increase the amount of the light emitted from the light-emitting device 10 to the light-emitting surface of the display device. The difference of the light-emitting efficiency of the light-emitting device 10 and other light-emitting devices 10 may be balanced, to improve the overall display effect of the display device.

For description purposes only, the embodiment in FIG. 10 with the contour shapes of the orthographical projection of the light-emitting devices 10 and the reflectors 30 is used as an example to illustrate the present disclosure, and does not limit the scope of the present disclosure. In some other embodiments, the shapes of the light-emitting devices 10 and the reflectors 30 may be adjusted according to actual needs, and the present disclosure has no limit on this.

In the embodiment shown in FIG. 10, the contour shapes of the orthographical projection of the light-emitting devices 10 with different light-emitting colors may be same. In some other embodiments, the contour shapes of the orthographical projection of the light-emitting devices 10 with different light-emitting colors may be different. For example, the contour shapes of the orthographical projection of the first-color light-emitting devices 11 may be rectangular, the contour shapes of the orthographical projection of the second-color light-emitting devices 12 may be square, and the contour shapes of the orthographical projection of the third-color light-emitting devices 13 may be circular.

Further, to further balance the difference of the light-emitting efficiency of the light-emitting devices 10 of different light-emitting colors, in one embodiment, the size of the light-emitting devices 10 with relatively low light-emitting efficiency may be increased correspondingly to increase the amount of the light emitted from the light-emitting devices 10 with relatively low light-emitting efficiency to the light-emitting surface of the display device.

In another embodiment shown in FIG. 10 which is a locally magnified view of the display region of the display device in FIG. 1, the orthographical projection of the reflector 30 corresponding to each light-emitting device 10 on the substrate 00 may have the same shape.

Specifically, when the reflectors 30 are disposed around the plurality of second light guide elements 22, in one embodiment, the contour shape of the orthographical projection of each reflector 30 on the substrate 00 may be a rectangle. When the contour shape of the orthographical projection of each reflector 30 is same, each reflector 30 may be formed with the same shape specifications, simplifying the manufacturing process of the reflectors 30 and improving the production efficiency of the display device.

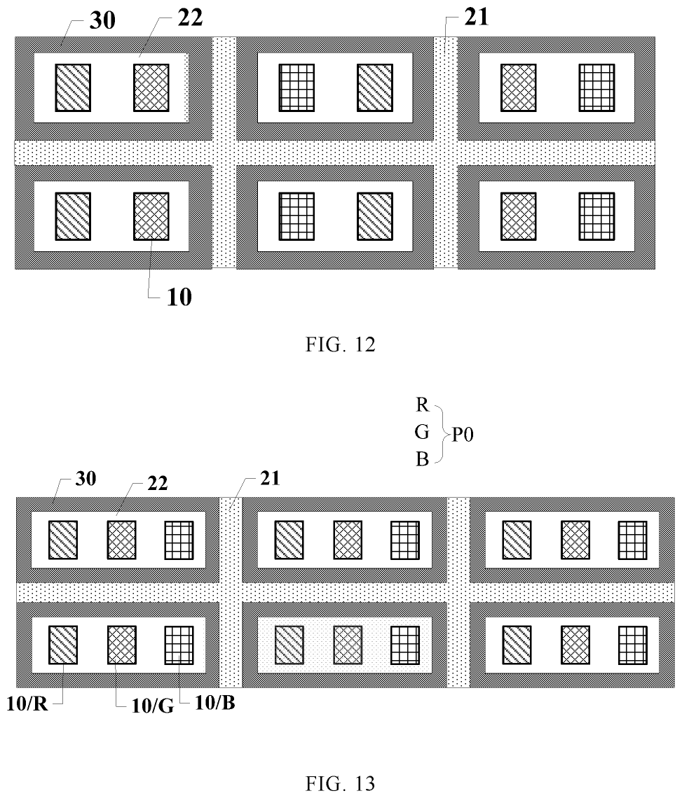

In the above embodiment, the light-emitting devices 10 and the plurality of second light guide elements 22 may be arranged in a one-to-one correspondence, that is, different light-emitting devices 10 may correspond to different second light guide elements 22. In some other embodiments, one second light guide element 22 may correspond to two or more light-emitting devices 10. For example, in one embodiment shown in FIG. 12 which is another locally magnified view of the display region of the display device in FIG. 1, one second light guide element 22 may cover at least two adjacent light-emitting devices 10, and one reflector 30 may be disposed surrounding one corresponding second light guide element 22.

In the embodiment shown in FIG. 12, two adjacent light-emitting devices 10 may be covered by one second light guide element 22. The light emitted from the two adjacent light-emitting devices 10 covered by the same one second light guide element 22 may be reflected by the second light guide element 22 and the corresponding reflector 30, and then directed to the light-emitting surface of the display device. By making the at least two adjacent light-emitting devices 10 be covered by one second light guide element 22, the size of one second light guide element 22 may be increased and the manufacturing difficulty of the second light guide element 22 may be reduced. Further, by making the at least two adjacent light-emitting devices 10 be covered by one second light guide element 22, the number of the plurality of second light guide elements 22 in the display device may be reduced significantly, therefore reducing the manufacturing difficulty of the plurality of second light guide elements 22. The production efficiency of the display device may be improved while improving the overall light-emitting efficiency of the display device.

For description purposes only, the embodiment in FIG. 12 where one second light guide element 22 covers two light-emitting devices 10 is used as an example to illustrate the present disclosure, and does not limit the scope of the present disclosure. In some other embodiments, one second light guide element 22 covers more than two light-emitting devices 10. In various embodiments, the corresponding relationship between the light-emitting devices 10 and the plurality of second light guide elements 22 may include that each of a portion of the plurality of second light guide elements 22 covers a same number of light-emitting devices 10 or each of a portion of the plurality of second light guide elements 22 covers a different number of light-emitting devices 10. For example, each of a portion of the plurality of second light guide elements 22 may cover two light-emitting devices 10, and each of another portion of the plurality of second light guide elements 22 may cover two light-emitting devices 10 may cover three light-emitting devices 10. The present disclosure has no limit on this.

As shown in FIG. 12, in one embodiment, each of at least a portion of the plurality of second light guide elements 22 may cover a same number of light-emitting devices 10.

Specifically, in one embodiment, each second light guide element 22 may cover a same number of light-emitting devices 10. For example, each second light guide element 22 may cover two light-emitting devices 10. When each second light guide element 22 covers a same number of light-emitting devices 10, the size of each second light guide element 22 may have a same or similar size. Correspondingly, different second light guide element 22 may be formed with same size specifications, therefore simplifying the manufacturing process of the plurality of second light guide elements and the display device. Further, when one second light guide element 22 covers two or more light-emitting devices 10, the number of the plurality of second light guide elements 22 in the display device may be reduced significantly, therefore simplifying the manufacturing process of the display device.

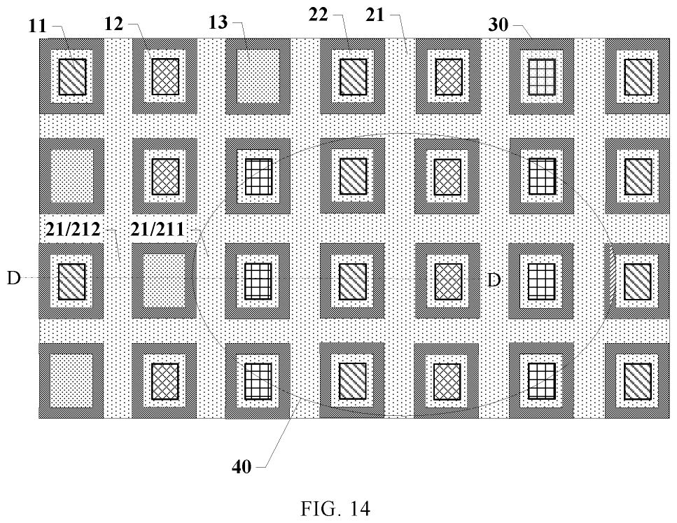

In one embodiment shown in FIG. 13 which is a positional relationship of pixel units P0 and the plurality of second light guide elements 22 in the display device, the display device may include a plurality of pixel units P0, and each of the plurality of pixel units P0 may include three light-emitting devices 10 with three different light-emitting colors respectively. One second light guide element 22 may cover one of the plurality of pixel units P0.

In one embodiment, the display device may include the plurality of pixel units P0, and the plurality of pixel units P0 and the plurality of second light guide elements 22 may have a positional relationship. Optionally, each of the plurality of pixel units P0 may include three light-emitting devices 10 with three different light-emitting colors respectively. For example, the three light-emitting devices 10 with three different light-emitting colors respectively may be a red light-emitting device R, a green light-emitting device G, and a blue light-emitting device B. In some other embodiments, each of the plurality of pixel units P0 may include four light-emitting devices 10 with four different light-emitting colors respectively. For example, the four light-emitting devices 10 with four different light-emitting colors respectively may be a red light-emitting device, a green light-emitting device, a blue light-emitting device, and a white light-emitting device.

In one embodiment, the plurality of second light guide elements 22 and the plurality of pixel units P0 may be disposed in a one-to-one correspondence, that is, one second light guide element 22 may cover a plurality of light-emitting devices 10 corresponding to a corresponding pixel unit P0 of the plurality of pixel units. When the display panel uses the plurality of pixel units P0 for display, different light-emitting devices 10 in one same pixel unit P0 of the plurality of pixel units P0 may form a predetermined color picture by color mixing. In this embodiment, one same second light guide element 22 may cover one corresponding pixel unit P0. When the light-emitting devices 10 in the pixel unit P0 covered by the same second light guide element 22 emit light, at least part of the light is transmitted to the corresponding reflector 30 through the second light guide element 22, and then return to the second light guide element 22 after being reflected by the reflector 30. The light may be emitted from the light-emitting surface of the display device after multiple reflections, thereby helping to improve the light-emitting efficiency of each light-emitting device 10 in the pixel unit P0. When displaying a color image, since each light-emitting device 10 in the same pixel unit P0 itself needs to mix light, when the same pixel unit P0 is covered by the same second light guide element 22 and the surrounding area of the second light guide element 22 is covered by the reflector 30, the reflector 30 may act as a blocking wall, effectively avoiding the phenomenon of light mixing between adjacent pixel units P0 and helping to improve the display effect of the display device. Further, by disposing the plurality of second light guide elements 22 and the plurality of pixel units P0 in a one-to-one correspondence, the number of plurality of second light guide elements 22 included in the display device may be further reduced, therefore simplifying the manufacturing process of the plurality of second light guide elements 22.

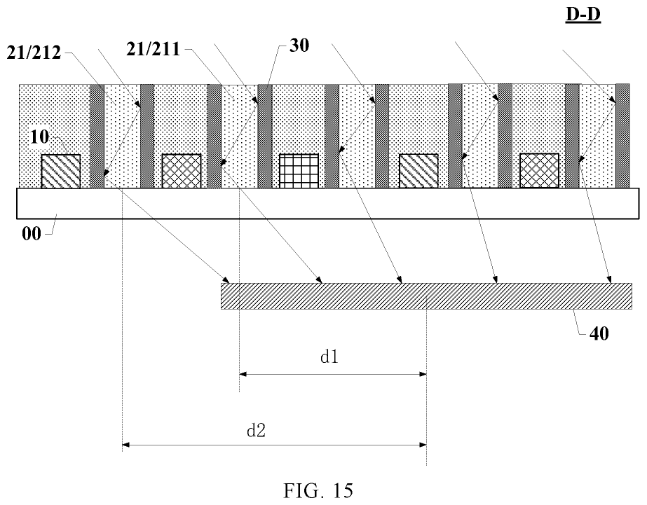

In one embodiment shown in FIG. 14 which illustrates a top view of the first light guide elements 21 and the photosensitive units 40 in the display device and FIG. 15 which is a cross-sectional view of the display device in FIG. 14 along a DD direction, the relationship of the film layers of the first light guide elements 21 and the photosensitive units 40 may be configured as shown in FIG. 14 and FIG. 15. In the present embodiment, the photosensitive units 40 may include sensors arranged in an array. Along the first direction, each photosensitive unit 40 may overlap a plurality of first light guide elements 21. The plurality of first light guide elements 21 overlapping one same photosensitive unit 40 may include a first sub-light guide element 211 and a second sub-light guide element 212. In the direction parallel to the substrate 00, a distance between the geometric center of the orthographic projection of the first sub-light guide element 211 on the substrate 00 and the geometric center of the photosensitive unit 40 is d1, and a distance between the geometric center of the orthographic projection of the second sub-light guide element 212 on the substrate 00 and the geometric center of the photosensitive unit 40 is d2, where d1<d2. The refractive index difference between the first sub-light guide element 211 and its adjacent reflector 30 is s1, and the refractive index difference between the second sub-light guide element 212 and the reflector 30 adjacent thereto is s2, where s1<s2. The first direction may be perpendicular to the substrate.

As shown in FIGS. 14 and 15, in one embodiment, the plurality of photosensitive units 40 may be arranged on the side of the substrate 00 away from the light-emitting devices 10. The light guided by one first light guide element 21 may be transmitted from two corresponding adjacent light-emitting devices 10 to one corresponding photosensitive unit 40. Optionally, each photosensitive unit 40 may include sensors arranged in an array, and any sensor is able to convert the light signal into an electrical signal when it receives the light guided through the first light guide elements 21. It can be understood that, part of the light emitted to the photosensitive units 40 through the first light guide elements 21 may be inclined, that is, may be not perpendicular to the plane where the substrate 00 is located. Correspondingly, when the photosensitive units 40 are not provided directly below one first light guide element 21, the oblique light may also enter the photosensitive unit 40 adjacent to the position directly below the first light guide element 21. Therefore, along the direction perpendicular to the plane where the substrate 00 is located, one photosensitive unit 40 provided in the embodiment may not overlap with the corresponding first light guide element 21. Of course, in some other embodiments, the photosensitive unit 40 and the corresponding first light guide element 21 may also be arranged to overlap in the direction perpendicular to the substrate 00. The perpendicularly emitted or obliquely emitted light from one first light guide element 21 may be directed to the corresponding photosensitive unit 40, therefore increasing the amount of light that the photosensitive unit 40 is able to receive and improving the photosensitive performance of the photosensitive unit 40.

In one embodiment, along the direction perpendicular to the plane where the substrate 00 is located, one photosensitive unit 40 may correspond to a plurality of first light guide elements 21. For example, the plurality of first light guide elements 21 corresponding to one same photosensitive unit 40 may include the first sub-light guide element 211 and the second sub-light guide element 212. The distance d1 between the first sub-light guide element 211 and the geometric center of the corresponding photosensitive unit 40 may be smaller than the distance d2 between the second sub-light guide element 212 and the geometric center of the corresponding photosensitive unit 40. That is, the first sub-light guide element 211 may be closer to the geometric center of the corresponding photosensitive unit 40 and the second sub-light guide element 212 may be farther from the geometric center of the corresponding photosensitive unit 40. When the refractive index difference between the first sub-light guide element 211 and its corresponding reflector 30 is the same as the refractive index difference between the second sub-light guide element 212 and its corresponding reflector 30, since the second sub-light guide element 212 is farther away from the geometric center of the corresponding photosensitive unit 40, the amount of light emitted from the second sub-light guide element 212 to the corresponding photosensitive unit 40 may be smaller than the amount of light emitted from the first sub-light guide unit 211 to the corresponding photosensitive unit 40. Therefore, in the present embodiment, the refractive index difference between the first sub-light guide element 211 and its corresponding reflector 30 may be designed to be different from the refractive index difference between the second sub-light guide element 212 and its corresponding reflector 30, such that the refractive index difference between the second sub-light guide element 212 that is far away from the geometric center of the corresponding photosensitive unit 40 and the reflector 30 corresponding thereto is designed to be larger. Correspondingly, the reflective efficiency of the corresponding reflector 30 on the second sub-light guide element 212 may be increased and more light may be transmitted from the second sub-light guide element 212 to the corresponding photosensitive unit 40. The amount of light that the photosensitive unit 40 is able to receive may be increased and the photosensitive precision of the photosensitive unit 40 may be improved.

In one embodiment, along a direction from a geometric center of one photosensitive unit 40 to the periphery, the refractive index differences between different first light guide elements 21 and the reflectors 30 adjacent thereto may gradually increase.

When one same photosensitive unit 40 corresponds to a plurality of first light guide elements 21, the distances between the geometric centers of different first light guide elements 21 and the photosensitive unit 40 may be not the same. In the present embodiment, the refractive index difference between one first light guide element 21 that is farther from the geometric center and its corresponding reflector 30 may be relatively large, while the refractive index difference between one first light guide element 21 closer to the geometric center and its corresponding reflector 30 may be relatively small. The refractive index differences between the first light guide elements 21 and the corresponding reflectors 30 may gradually change according to the change trend of the distance between the first light guide elements 21 and the geometric center, thereby increasing the amount of light transmitted by one first light guide element 21 farther from the geometric center to the photosensitive unit 40. The amount of light actually received by the photosensitive unit 40 and the uniformity of the amount of light received by the sensors at different positions of the photosensitive unit 40 may be improved, to improve the photosensitive accuracy of the photosensitive unit 40.

As shown in FIG. 15, in one embodiment, the light transmission structure may be multiplexed as an encapsulation layer of the display device.

In the display device provided by one embodiment of the present disclosure, the light transmission structure may be disposed on the side of the light-emitting devices 10 away from the substrate 00. The first light guide elements 21 may be disposed between two adjacent light-emitting devices 10, and the second light guide elements 22 may cover the light-emitting devices 10. The reflectors 30 may be provided between the first light guide elements 21 and the second light guide elements 22, and may cover the second light guide elements 22. The light transmission structure formed by the first light guide elements 21, the second light guide elements 22 and the reflectors 30 may coated above the light-emitting devices 10, and is able to function as an encapsulation layer. No encapsulation layer may be needed to be introduced into the display device, therefore simplifying the film layer structure of the display device, reducing the overall thickness of the display device, and meeting the light and thin requirements of the display device.

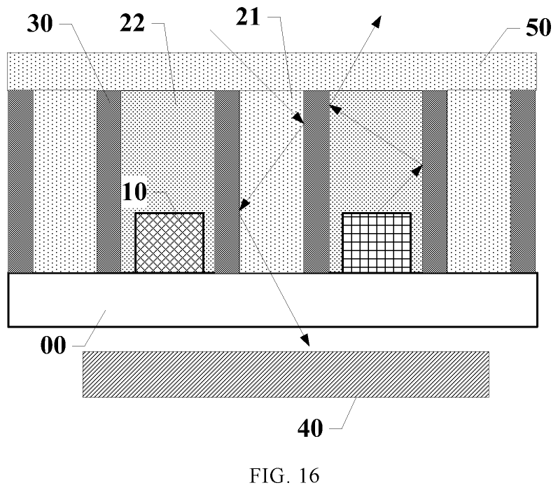

In another embodiment shown in FIG. 16 which illustrate another film layer structure of the display device, the display device may further include an encapsulation layer 50. The encapsulation layer 50 may be disposed at a side of the light transmission structure away from the substrate 00, and may have a refractive index same as the first light guide elements 21.

In the present disclosure, the encapsulation layer 50 may be provided in the display device. Specifically, the encapsulation layer 50 may be disposed at a side of the light transmission structure away from the substrate 00, to prevent water and impurities from contacting the light-emitting devices 10 and improve the reliability of the display device. Further, when the encapsulation layer 50 is provided, the encapsulation layer 50 may have a refractive index same as the first light guide elements 21. Correspondingly, the encapsulation layer 50 and the first light guide elements 21 may be made of the same material, which is beneficial to simplify the types of film layers of the display device and simplify the manufacturing process of the display device. Further, when the refractive index of the encapsulation layer 50 and the first light guide elements 21 are set to be the same, the reflection of light between the encapsulation layer 50 and the first light guide elements 21 may be avoided, to reduce the amount of the light from the first light guide elements 21 to the photosensitive units 40 and ensure the photosensitive accuracy.

In one embodiment shown in FIG. 16, the encapsulation layer 50 may have a refractive index same as the refractive index of the plurality of second light guide elements 22. The light emitted from the plurality of second light guide elements 22 may be prevented from reflection at the position of the encapsulation layer 50 to affect the light extraction rate of the display device. Further, when the encapsulation layer 50 has a refractive index same as the refractive index of the plurality of second light guide elements 22, the encapsulation layer 50 and the plurality of second light guide elements 22 may be made of a same material in a same manufacturing process, simplifying the manufacturing process of the display device and improve the production efficiency.

Optionally, the encapsulation layer 50, the first light guide elements 21 and the plurality of second light guide elements 22 may have the same refractive index, and may be made of the same material in the same manufacturing process. Therefore, the manufacturing process of the display device may be further simplified and the production efficiency may be improved, while improving the photosensitive performance and the light extraction rate.

In various embodiments, the display device may be embodied as any product or component with a display function, such as a mobile phone, a tablet computer, a TV, a monitor, a notebook computer, a digital photo frame, or a navigator, etc., and is especially suitable for a display device with a photosensitive function.

In the display device provided by the present disclosure, the light transmission structure may be arranged on the side of the light-emitting devices away from the substrate, and the plurality of photosensitive units may be arranged on the side of the substrate away from the light-emitting devices. The light transmission structure may include the first light guide elements and the reflectors arranged respectively at two sides of the first light guide elements. Along the direction perpendicular to the substrate, one first light guide element may be located between two adjacent light-emitting devices. The refractive index of the first light guide elements in the light transmission structure may be different from the refractive index of the reflectors. When light is transmitted to the interface between one first light guide element and one corresponding reflector, reflection may occur and the first light guide element may form a light guide channel, such that the light may be able to be transmitted between two corresponding adjacent light-emitting devices through the first light guide element and then be guided to the plurality of photosensitive units. Therefore, the amount of light transmitted to the plurality of photosensitive units may be increased to improve the photosensitive performance of the product. When the plurality of photosensitive units disposed on the side of the substrate away from the light-emitting devices are fingerprint identification units, the above-mentioned light guide channels may be able to transmit more light to the fingerprint identification units, thereby helping to improve the fingerprint identification accuracy of the product.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display device, comprising:
a substrate;
light-emitting devices on a side of the substrate;
light transmission structures on a side of the light-emitting devices away from the substrate; and
a plurality of photosensitive units on a side of the substrate away from the light-emitting device,
wherein:
each of the light transmission structures includes a first light guide element and reflectors arranged along a direction parallel to a plane of the substrate;
the reflectors are located at two sides of the first light guide element;
an orthographical projection of the first light guide element to the substrate is located between two corresponding adjacent light-emitting devices; and
the first light guide element has a refractive index n₁ and the reflectors have a refractive index no, wherein n₁≠n₀.

2. The display device according to claim 1, wherein n₁>n₀.

3. The display device according to claim 1, wherein:
the reflectors include a first reflector and a second reflector respectively located at two sides of the first light guide element; and
the refractive index of the first reflector is n₀₁, and the refractive index of the second reflector is n₀₂, wherein n₀₁=n₀₂.

4. The display device according to claim 3, wherein:
the first reflector and the second reflector are made of a same material.

5. The display device according to claim 3, wherein:
along a direction from the first reflector to the second reflector, the thickness of the first reflector and the thickness of the second reflector are same.

6. The display device according to claim 1, wherein:
the light transmission structures further include a plurality of second light guide elements;
along a first direction, the plurality of second light guide elements covers the light-emitting devices;
the plurality of second light guide elements has a refractive index n₂, wherein n₂>n₀; and
the first direction is perpendicular to the substrate.

7. The display device according to claim 6, wherein n₁=n₂.

8. The display device according to claim 6, wherein:
along the first direction, one same second light guide element of the plurality of second light guide elements covers one corresponding light-emitting device.

9. The display device according to claim 8, wherein:
the light-emitting devices include first-color light-emitting devices, second-color light-emitting devices, and third-color light-emitting devices;
second light guide elements of the plurality of second light guide elements corresponding to the first-color light-emitting devices, the second-color light-emitting devices, and the third-color light-emitting devices have same refractive indices respectively.

10. The display device according to claim 8, wherein:
the light-emitting devices include first-color light-emitting devices, second-color light-emitting devices, and third-color light-emitting devices;
the refractive indices of second light guide elements of the plurality of second light guide elements corresponding to the first-color light-emitting devices are n₂₁;
the refractive indices of second light guide elements of the plurality of second light guide elements corresponding to the second-color light-emitting devices are n₂₂;
the refractive indices of second light guide elements of the plurality of second light guide elements corresponding to the third-color light-emitting devices are n₂₃;
the refractive indices of the reflectors corresponding to the first-color light-emitting devices are n₀₁;
the refractive indices of the reflectors corresponding to the second-color light-emitting devices are n₀₂;
the refractive indices of the reflectors corresponding to the third-color light-emitting devices are n₀₃; and
n₂₁-n₀₁=n₂₂−n₀₂−n₂₃−n₀₃.

11. The display device according to claim 8, wherein:
the light-emitting devices include red light-emitting devices, green light-emitting devices, and blue light-emitting devices;
the refractive indices of second light guide elements of the plurality of second light guide elements corresponding to the red light-emitting devices are n₂₁;
the refractive indices of second light guide elements of the plurality of second light guide elements corresponding to the green light-emitting devices are n₂₂;
the refractive indices of second light guide elements of the plurality of second light guide elements corresponding to the blue light-emitting devices are n₂₃;
the refractive indices of the reflectors corresponding to the red light-emitting devices are n₀₁;
the refractive indices of the reflectors corresponding to the green light-emitting devices are n₀₂;
the refractive indices of the reflectors corresponding to the blue light-emitting devices are n₀₃; and
n₂₃−n₀₃>n₂₂−n₀₂>n₂₁−n₀₁.

12. The display device according to claim 8, wherein:
along an arrangement direction of the light-emitting devices, an interval between any two adjacent reflectors has a same width.

13. The display device according to claim 8, wherein:
a contour shape of an orthographic projection of one light-emitting device on the substrate is same as a contour shape of an orthographic projection of one of the reflectors corresponding to the light-emitting device on the substrate.

14. The display device according to claim 8, wherein:
an outer edge of a contour of an orthographic projection of one light-emitting device on the substrate is a first edge;
an inner edge of a contour of an orthographic projection of one of the reflectors corresponding to the light-emitting device on the substrate is a second edge;
a distance between the first edge and the second edge corresponding to each light-emitting device is same.

15. The display device according to claim 8, wherein:
orthographic projections of the reflectors corresponding to the light-emitting devices of a same color on the substrate have different shapes;
the shapes of the reflectors corresponding to the light-emitting devices of the same color include a first shape and a second shape; and
along the arrangement direction of the light-emitting devices, the first shape and the second shape are alternately arranged.

16. The display device according to claim 6, wherein:
one of the plurality of second light guide elements covers at least two corresponding adjacent light-emitting devices; and
one of the reflectors is arranged around a corresponding one of the plurality of second light guide elements.

17. The display device according to claim 16, wherein:
each of at least a portion of the plurality of second light guide elements covers a same number of light-emitting devices.

18. The display device according to claim 16, further including a plurality of pixel units, wherein:
each of the plurality of pixel units includes at least three light-emitting devices with different light-emitting colors, and one of the plurality of second light guide elements covers one of the plurality of pixel units.

19. The display device according to claim 1, wherein:
each of the plurality of photosensitive units includes sensors arranged in an array;
along a first direction, one of the plurality of photosensitive units overlaps with a plurality of first light guide elements;
first light guide elements overlapped with a same one of the plurality of photosensitive units include a first sub-light guide element and a second sub-light guide element;
along a direction parallel to the substrate, a distance between a geometric center of an orthographic projection of the first sub-light guide element on the substrate and a geometric center of a corresponding one of the plurality of photosensitive units is d1, and a distance between a geometric center of an orthographic projection of the second sub-light guide element on the substrate and the geometric center of the corresponding one of the plurality of photosensitive units is d2, wherein d1<d2; and
a refractive index difference between the first sub-light guide element and its adjacent reflector is s1, and a refractive index difference between the second sub-light guide element and its adjacent reflector is s2, wherein s1<s2 and the first direction is perpendicular to the substrate.

20. The display device according to claim 19, wherein:
along a direction from a geometric center of one of the plurality of photosensitive units to periphery thereof, differences of refractive indices between different first light guide elements and the reflectors adjacent to corresponding first light guide elements gradually increase.
